(19) United States
(12) Patent Application Publication
(10) Pub. No.: US 2005/0072624 A1
(43) Pub. Date: Apr. 7, 2005

(54) Speaker

(75) Inventors: Jae Hwan Ryu, Osan City (KR); Ki Hun Kim, Anyang City (KR)

Correspondence Address: BIRCH STEWART KOLASCH & BIRCH, PO BOX 747, FALLS CHURCH, VA, 22040-0747, US

(73) Assignee: LG Electronics Inc., Seoul (KR)

(21) Appl. No.: 10/935,082

(22) Filed: Sep. 8, 2004

(30) Foreign Application Priority Data
Oct. 6, 2003 (KR) 2003-0069369
Oct. 31, 2003 (KR) 2003-0076945

(51) Int. Cl. A47B 81/06; H05K 5/00

(52) U.S. Cl. 181/199; 181/148; 181/160

(57) ABSTRACT

The present invention relates to a speaker. The speaker comprises a first cabinet 20 with a predetermined inner space 22 defined therein; a second cabinet 30 in which an inner space 32 communicating with the inner space 22 of the first cabinet 20 is defined so that the inner space 22 is closed from the outside when the second cabinet 30 is engaged with the first cabinet 20; and a sound-generating unit 40 provided in the inner spaces 22 and 32 defined by the first and second cabinets 20 and 30 to generate an acoustic signal. The first and second cabinets 20 and 30 can move relatively with respect to each other, whereby an internal volume of the inner spaces 22 and 32 is changed through adjustment of the length D of the inner spaces 22 and 32 between a front end of the first cabinet 20 and a rear end of the second cabinet 30. According to the speaker of the present invention constructed as above, since the internal volume of the inner spaces defined in the cabinets, the length of the duct, and the like can be adjusted by a user, there are advantages in that it is possible to generate sounds in a bass band according to user's taste and to easily and securely mount a duct formed separately from the cabinets in the cabinets.

### BACKGROUND OF THE INVENTION

1. Field of Invention

The present invention relates to a speaker, and more particularly, to a speaker for converting electric signals into audible acoustic signals.

2. Description of the Prior Art

A speaker, which is an acoustic device for converting electric signals into vibrations of a diaphragm to generate waves of condensation and rarefaction and to radiate acoustic waves, is configured such that a sound-generating unit for generating sounds is mounted in a cabinet.

FIG. 1 is a schematic view showing a conventional speaker. Referring to the figure, an external appearance of the speaker is defined by a cabinet 1. The cabinet 1 is made in the form of a box, generally a hexahedron, in which a predetermined inner space 3 is defined.

A front surface of the cabinet 1 is formed with a predetermined vent portion 5. A sound-generating unit 7 is installed behind the vent portion 5, i.e. in the inner space 3 of the cabinet 1. The sound-generating unit 7 is a part that actually converts electric signals into acoustic signals.

A portion of a sound generated from the sound-generating unit 7 is transmitted into the inner space 3 of the cabinet 1. In order to guide the sound transmitted to the inner space 3 of the cabinet 1, the inner space 3 may be formed with an additional duct 9. The duct 9 may be formed such that the inner space 3 communicates with the outside.

However, the conventional speaker described above has the following problems.

In the conventional speaker, the inner space 3 of the cabinet I defining the external appearance has a predefined internal volume. That is, the depth D of the inner space 3, which corresponds to a distance from an inner front surface to an inner rear surface of the cabinet 1, has been fixed.

Therefore, once a speaker is manufactured, properties of generated acoustic signals are monolithically nearly identical with one another and cannot be changed differently. After all, a user can utilize only speakers having monolithic properties designed by manufacturers. Particularly, since the depth D of the inner space 3 greatly influences generation of sounds of a bass band, there is a problem in that it is impossible for a user to listen to sounds falling within the band according to his/her taste.

Furthermore, the speaker outputs a resultant sound obtained through superposition of a sound generated from the sound-generating unit 7 on a resonant sound produced by the cabinet 1 and the duct 9 after generation from the sound-generating unit 7. Here, the length L of the duct 9 is a factor for determining a bass sound property. Therefore, the duct 9 having the constant length in the conventional speaker exhibits only a monolithic bass sound property.

### SUMMARY OF THE INVENTION

Accordingly, the present invention is conceived to solve the aforementioned problems in the prior art. An object of the present invention is to provide a speaker, wherein the internal volume of an inner space defined in the speaker can be changed according to user's taste.

Another object of the present invention is to provide a speaker, wherein the length of a duct installed in the speaker can be changed.

A further object of the present invention is to provide a speaker, wherein a duct formed separately from a cabinet can be more easily and securely mounted in the cabinet.

According to an aspect of the present invention for achieving the objects, there is provided a speaker, comprising a first cabinet with a predetermined inner space defined therein; a second cabinet in which an inner space communicating with the inner space of the first cabinet is defined so that the inner space of the first cabinet is closed from the outside when the second cabinet is engaged with the first cabinet; and a sound-generating unit provided in the inner spaces defined by the first and second cabinets to generate an acoustic signal. The first and second cabinets can move relatively with respect to each other, whereby an internal volume of the inner spaces is changed through adjustment of the length of the inner spaces between a front end of the first cabinet and a rear end of the second cabinet.

The first and second cabinets may be formed to take the shape of a cylinder, and an outer surface of one of the first and second cabinets and an inner surface of the other thereof may be formed with thread portions corresponding to each other, respectively.

A lower portion of an outer one of the first and second cabinets may be provided with a base for supporting them on a floor.

The exterior of an outer one of the first and second cabinets may be provided with an enclosure.

The speaker may further comprise a duct for causing the inner spaces defined by the first and second cabinets to communicate with the outside. The length of the duct can be adjusted.

The duct may comprise a plurality of connected pipes with gradually varying inner diameters, thereby adjusting the length of the duct.

The speaker may further comprise a duct for causing the inner spaces defined by the first and second cabinets to communicate with the outside. A rear end of the duct may be supported at the second cabinet by an elastic member.

The duct may be provided with a rear end flare portion of which an inner diameter increases toward the rear end of the duct, and one end of the elastic member may be seated in the rear end flare portion and the other end thereof may be fixed to the second cabinet to support the duct.

The speaker may further comprise gaskets between the rear end of the duct and the elastic member and between a front end of the duct and an inner connection portion of the first cabinet connected thereto, respectively, thereby absorbing vibrations.

The first and second cabinets may be made of a ceramic material.

According to the speaker of the present invention constructed as above, since the internal volume of the inner space defined in the cabinet, the length of the duct, and the like may be adjusted by a user, there are advantages in that it is possible to properly generate sounds of a bass band according to user's taste and to easily and securely mount the duct, which is formed separately from the cabinet, in the cabinet.

### BRIEF DESCRIPTION OF THE DRAWINGS

The above and other objects, features and advantages of the present invention will become apparent from the following description of preferred embodiments given in conjunction with the accompanying drawings, in which:

FIG. 1 is a schematic sectional view showing the interior of a conventional speaker;

FIG. 2 is a schematic sectional view showing the structure of a first embodiment of a speaker according to the present invention;

FIG. 3 is a schematic front view showing the structure of the first embodiment of the present invention;

FIG. 4 is a view showing a use state of the first embodiment of the present invention;

FIG. 5 is a schematic front view showing the structure of a second embodiment of the present invention;

FIG. 6 is a schematic sectional view showing the structure of a third embodiment of the present invention;

FIG. 7 is a view showing a use state of the third embodiment of the present invention;

FIG. 8 is a schematic sectional view showing the structure of a fourth embodiment of the present invention;

FIG. 9 is a perspective view showing a duct of the fourth embodiment of the present invention;

FIG. 10 is a graph showing acoustic properties of the first embodiment of the present invention; and

FIG. 11 is a graph showing acoustic properties of the third embodiment of the present invention.

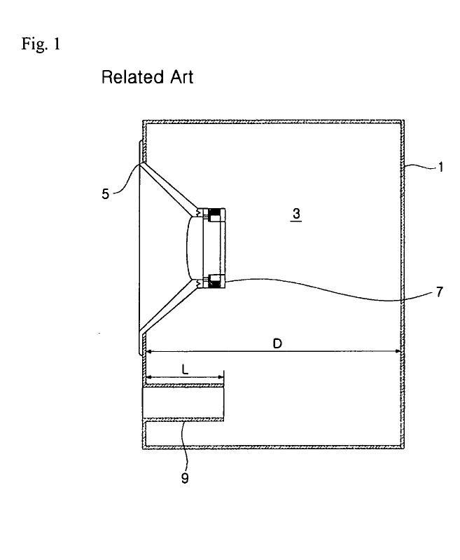

### DETAILED DESCRIPTION OF THE PREFERRED EMBODIMENT

Hereinafter, preferred embodiments of a speaker according to the present invention will be described in detail with reference to the accompanying drawings.

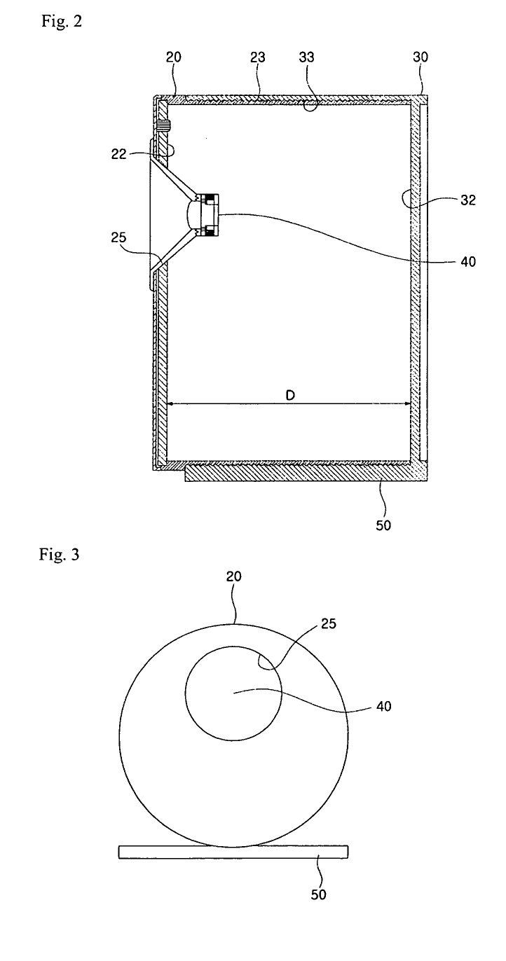

FIG. 2 is a schematic sectional view showing the structure of a first embodiment of a speaker according to the present invention, and FIG. 3 is a schematic front view showing the structure of the first embodiment of the present invention.

Referring to the figures, the speaker of the first embodiment of the present invention is provided with a first cabinet 20. The first cabinet 20 takes the shape of a cylinder, and a front face thereof defines a front surface of the speaker and a rear face thereof is open. A predetermined inner space 22 is defined within the first cabinet 20. The inner space 22 may communicate with the outside through the rear face of the first cabinet 20 when only the first cabinet 20 is separated.

A thread portion 23 is formed around an outer surface of the first cabinet 20. The thread portion 23 is formed from a rear end nearly to a front end of the first cabinet 20. The thread portion 23 functions to cause the first cabinet 20 to be engaged with a second cabinet 30 to be described later, so that they can move relatively with respect to each other.

The front surface of the first cabinet 20 is provided with a vent portion 25. The vent portion 25 is formed such that the center thereof is positioned to be eccentric from the center of the first cabinet 20. According to design conditions, the center of the front face of the first cabinet 20 may coincide with the center of the vent portion 25.

The second cabinet 30 is rotatably engaged with the first cabinet 20. In this embodiment, the first cabinet 20 is positioned within the second cabinet 30. The second cabinet 30 also takes the shape of a cylinder and has an inner space 32 therein that is open at a front face of the second cabinet 30.

A thread portion 33, which will be engaged with the thread portion 23 formed around the outer surface of the first cabinet 20, is formed around an inner surface of the second cabinet 30. Therefore, if an engagement width of the thread portions 23 and 33 is adjusted, the internal volume of the inner spaces 22 and 32 defined in the first and second cabinets 20 and 30 can also be adjusted.

A sound-generating unit 40 is installed in the inner spaces 22 and 32. In this embodiment, it is installed at a position within the first cabinet 20 corresponding to the vent portion 25. The sound-generating unit 40 functions to convert electric signals into acoustic signals.

A base 50 may be provided at a lower portion of the second cabinet 30. The base 50 prevents the second cabinet 30 from rolling inadvertently. The base 50 is formed to take the shape of a plate having a predetermined area.

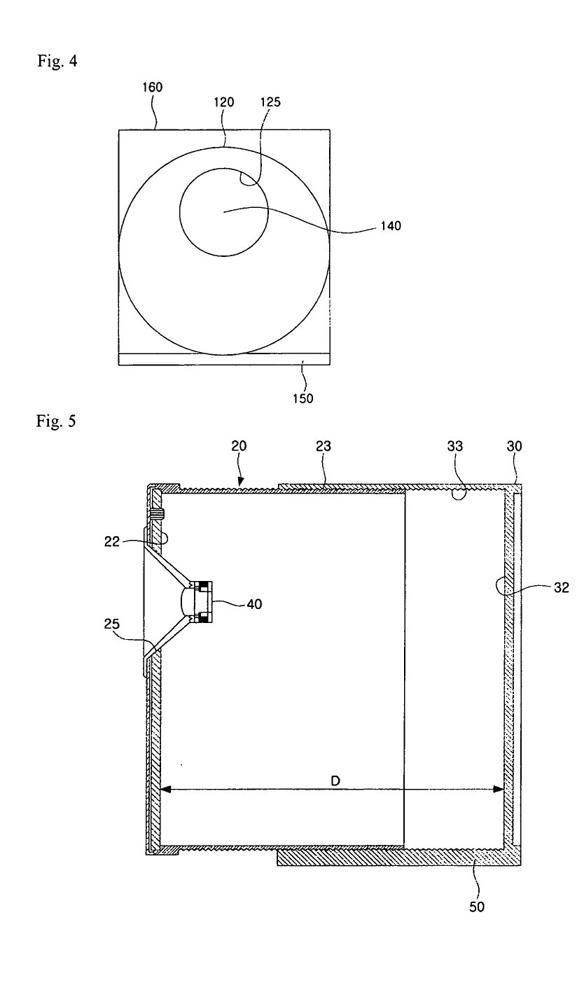

Next, FIG. 4 shows a second embodiment of the present invention. For convenience of description, reference numerals increased by one hundred are given to the same elements as the first embodiment, and only major portions will be described.

In this embodiment, a first cabinet 120 is formed to take the shape of a cylinder, and a second cabinet 130 is also formed to take the shape of a cylinder. An outer surface of the first cabinet 120 and an inner surface of the second cabinet 130 are formed with corresponding thread portions.

Then, an enclosure 160 is provided around the second cabinet 130. The enclosure 160, which defines an external appearance of a speaker, may be formed integrally with the second cabinet 130 in practice. That is, the enclosure 160, a base 150 and the like are formed integrally with the second cabinet 130, and an inner space 132 of the second cabinet 130 is defined in the form of a cylinder corresponding to an external appearance of the first cabinet 120.

Here, the enclosure 160 may be formed in various shapes. For example, the enclosure 160 may be formed to generally take the shape of a hexahedron along with the base 150.

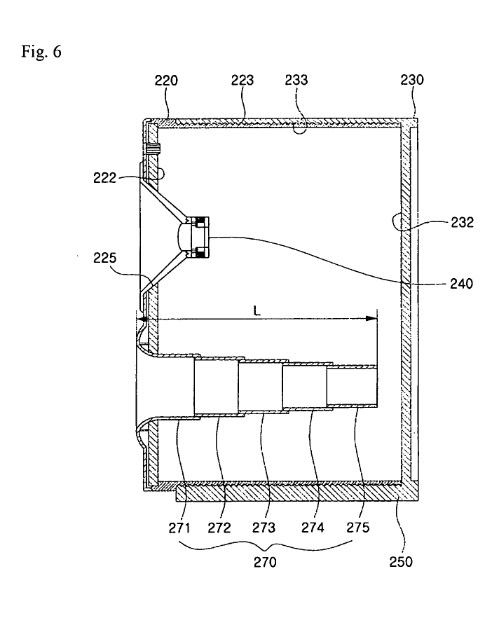

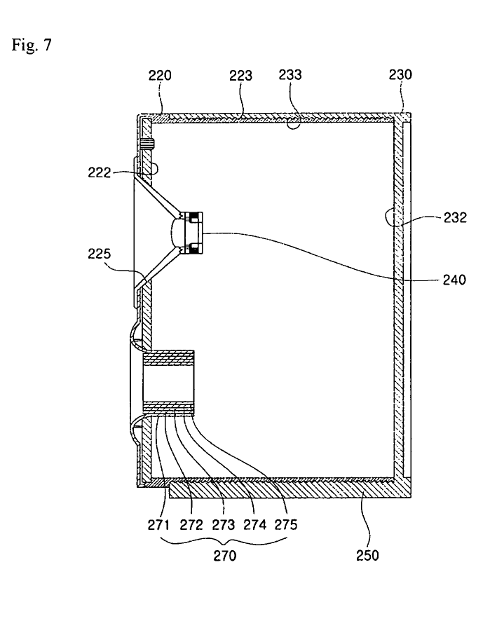

FIG. 6 shows a third embodiment of the present invention. For convenience of description, reference numerals increased by two hundreds are given to the same elements as the first embodiment, and only major portions will be described.

In this embodiment, first and second cabinets 220 and 230 define an external appearance of a speaker. A description of details thereof will be omitted. A duct 270 is provided to be open at a front face of the first cabinet 220. The duct 270 comprises first to fifth pipes 271 to 275. The inner diameters of the first to fifth pipes 271 to 275 gradually increase from the first pipe 271 having the largest inner diameter to the fifth pipe 275 having the smallest inner diameter.

As for the first to fifth pipes 271 to 275, pipes having relatively smaller inner diameters are telescopically inserted into corresponding pipes having relatively larger inner diameters to change the overall length L thereof. The first to fifth pipes 271 to 275 can be connected to one another by press-fitting the pipes having relatively smaller inner diameters into the corresponding pipes having relatively larger inner diameters. Ends of the respective first to fifth pipes 271 to 275 may be provided with stoppers so that they are not pulled out from one another.

Furthermore, the length L of the duct 270 may be adjusted by changing the width of engagement of a thread portion of an outer surface of one of the first to fifth pipes 271 to 275 with a corresponding thread portion of an inner surface of another adjacent one in the same manner as the first and second cabinets 220 and 230.

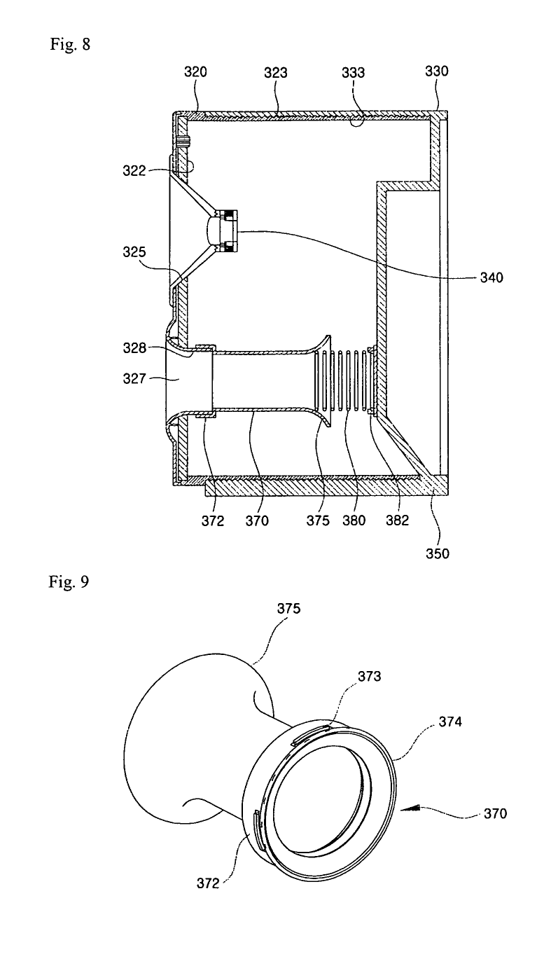

FIG. 8 shows a fourth embodiment of the present invention. For convenience of description, reference numerals increased by three hundreds are given to the same elements as the first embodiment, and only major portions will be described.

Even in this embodiment, first and second cabinets 320 and 330 define an external appearance of a speaker. The cabinets 320 and 330 are preferably made of a ceramic material. If the cabinets 320 and 330 are made of the ceramic material, it is possible to implement a variety of designs thereof ac compared with wood. In addition, vibrations caused by sounds generated from a sound-generating unit 340 can be effectively prevented from being transmitted to the cabinets 320 and 330.

A portion of a front surface of the first cabinet 320 is formed with a duct vent 327. The duct vent 327 causes an inner space 322 of the first cabinet 320 to communicate with the outside. An edge of the duct vent 327 is formed with an inner connection portion 328 to protrude toward the inner space 322.

In the meantime, the sound-generating unit 340 is mounted at a position within the first cabinet 320 corresponding to a vent 325 formed in the front surface of the first cabinet 320. For example, if the sound-generating unit 340 mainly generates bass sounds, its mounting position is not so important. This is because bass sounds do not have directionality. Therefore, in the case where the sound-generating unit 340 mainly generates bass sounds, it may be mounted at various positions other than the position in this embodiment shown in the figure.

A duct 370 is connected to the duct vent 327. The duct 370 functions to transmit sounds, which have been generated from the sound-generating unit 340 and transmitted to the inner spaces 322 and 332 of the cabinets 320 and 330, to the outside. The shape of the duct 370 is well shown in FIG. 9.

A front end of the duct 370 is provided with a front end-connecting portion 372 that is connected to the inner connection portion 328. It is preferred that an inner diameter of the front end-connecting portion 372 be determined to correspond to an outer diameter of the inner connection portion 328. Catching projections 373 are formed around an outer peripheral surface of the front end-connecting portion 372. It is preferred that a plurality of catching projections 373 be formed at a constant interval. The catching projections 373 regulate an installation position of a gasket 374 installed around a front end of the front end-connecting portion 372.

The gasket 374 has the function of absorbing sounds. That is, the gasket 374 functions to absorb vibrations of the duct 370 resulting from vibrations generated from the sound-generating unit 340. The gasket 374 may be provided between a rear end of the duct 370 and an elastic member 380 to be described below.

The duct 370 is provided with a rear end flare portion 375 of which the diameter increases toward a rear end thereof. The rear end flare portion 375 is formed such that the inner diameter of the duct gradually increases from a predetermined position on a rear side of the duct 370 toward the rear end thereof. The formation of the rear end flare portion 375 at the rear end of the duct 370 is to facilitate the coupling of the elastic member 380, which will be described below, to the duct. A seating step on which the elastic member 380 is to be seated may be provided around an inner surface of the rear end flare portion. Furthermore, although the duct 370 is formed as a single piece in this embodiment, the duct may comprise a plurality of pieces as in the third embodiment.

The elastic member 380 is installed between the rear end of the duct 370 and an inner surface of the second cabinet 330. The elastic member 380 functions to support the rear end of the duct 370, wherein one end of the elastic member 380 is supported by a fixing ring 382 installed on the inner surface of the second cabinet 330, and the other end thereof is supported at the inside of the rear end flare portion 375 of the duct 370. If the rear end of the duct 370 is supported using an elastic force of the elastic member 380 as described above, it is not necessary to use an additional fastener such as an adhesive or a screw.

Particularly, a coil spring is used as the elastic member 380. Even when the internal volume is changed by changing an engagement position of the first and second cabinets 320 and 330, the rear end of the duct 370 can be stably supported.

Here, the elastic member 380 not only supports the duct 370, but also functions to maintain a predetermined spacing between the duct 370 and the inner surface of the second cabinet 330. This is to smoothly transmit bass sounds generated from the sound-generating unit 340 and reflected sounds thereof to the front of the speaker, for example, in a case where the sound-generating unit 340 generates bass sounds. That is, the elastic member 380 causes the constant spacing to be defined between the duct 370 and the inner surface of the second cabinet 330.

Hereinafter, the operation of the speaker according to the present invention constructed as above will be described in detail.

First, the speaker of the first embodiment according to the present invention makes it possible to change the internal volume of the inner spaces 22 and 32 defined by the first and second cabinets 20 and 30. That is, the internal volume can be changed by changing the degree of engagement of the thread portion 23 formed on the outer surface of the first cabinet 20 with the thread portion 33 formed on the inner surface of the second cabinet 30.

For example, if the engagement width of the thread portions 23 and 33 is changed by rotating the first cabinet 20 with respect to the second cabinet 30, the front end of the first cabinet 20 and a rear end of the second cabinet 30 get away from or close to each other. Thus, the internal volume of the inner spaces 22 and 32 is changed. That is, the depth D of the inner spaces, which is the length between the front end of the first cabinet 20 and the rear end of the second cabinet 30, relatively increases or decreases.

That is, when the first and second cabinets 20 and 30 are positioned as shown in FIG. 2, the internal volume of the inner spaces 22 and 32 becomes relatively small. On the other hand, when the first cabinet 20 rotates with respect to and relatively protrudes from the second cabinet 30 as shown in FIG. 5, the internal volume of the inner spaces 22 and 32 becomes relatively large. That is, the depth D of the inner spaces of the cabinets 20 and 30 relatively increases.

If the internal volume of the inner spaces 22 and 32 defined by the first and second cabinets 20 and 30 is changed as described above, it is possible to change properties of sounds, particularly sounds of a bass band, which are generated from the speaker.

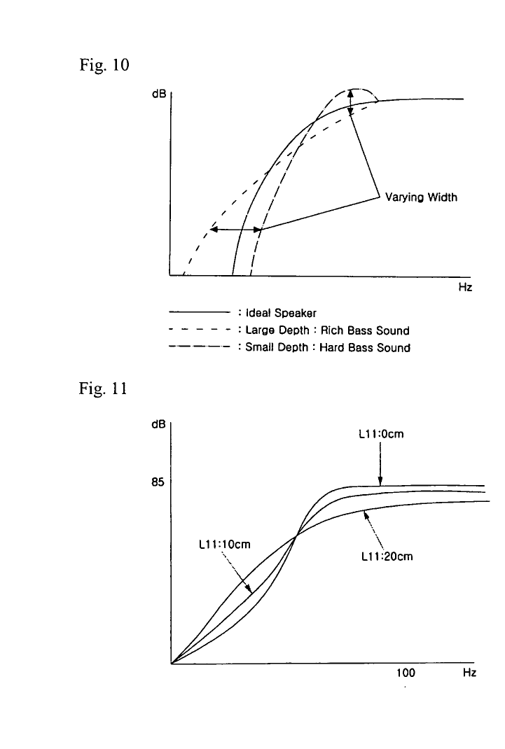

FIG. 10 shows properties of acoustic signals generated when the depth D of the inner spaces of the cabinets 20 and 30 is changed differently, wherein a solid line represents an ideal acoustic signal property.

A dotted line represents a case where the depth D becomes relatively large to generate relatively rich bass sounds. On the other hand, a dotted line represent a case where the depth D becomes relatively small to generate relatively hard bass sounds.

Next, the third embodiment shown in FIG. 6 makes it possible to freely change the length L of the duct 270. That is, the length L of the duct 270 may be adjusted by changing the degrees of engagement of the pipes 271 to 275. This may be performed together with the adjustment of the internal volume through the changing of the engagement width of the first and second cabinets 220 and 230.

Therefore, it is preferred that the lengths or the number of the pipes be determined such that the maximum length L of the duct 270 causes the rear end of the duct 270 to be close to a rear surface of the second cabinet 230 when the internal volume is maximum.

Bass sound properties may be particularly changed by adjusting the length of the duct 270 as described above. A graph shown in FIG. 11 represents bass sound properties that can be obtained when the length of the duct 270 is adjusted differently.

Next, in the embodiment shown in FIG. 8, the elastic member 380 supports the rear end of the duct 370. The elastic member 380 is installed in a state where it can be deformed elastically between the rear end flare portion 375 of the duct 370 and the inner surface of the second cabinet 330. Therefore, the elastic force of the elastic member 380 can support the rear end of the duct 370.

In the case where the elastic member 380 supports the rear end of the duct 370, it is not necessary to additionally fix the rear end of the duct 370 to the second cabinet 330 and the like. Thus, the rear end of the duct 370 can be fixed relatively easily. This structure is useful particularly when the length of the duct 370 is long.

Particularly, in the fourth embodiment according to the present invention, the first and second cabinets 320 and 330 are made of the ceramic material. Therefore, it is possible to form a variety of external designs due to the properties of the ceramic and to reduce the transmission of the vibrations resulting from sounds generated from the sound-generating unit 340 to other parts.

The scope of the present invention is not limited to the embodiments described and illustrated above but is defined by the appended claims. It will be apparent that those skilled in the art can make various modifications and changes thereto within the scope of the invention defined by the claims.

For example, although in the first embodiment of the present invention, the outer surface of the first cabinet 20 and the inner surface of the second cabinet 30 are formed with the thread portions 23 and 33, respectively, an inner surface of the first cabinet 20 and an outer surface of the second cabinet 30 may be formed with thread portions in an opposite manner. In such a case, the base 50 should be installed at a lower portion of the first cabinet 20, or the enclosure 60 should be installed around the first cabinet 20.

According to the speaker of the present invention described in detail above, it is expected to obtain the following advantages.

First, in the present invention, since a cabinet is formed of the separate first and second cabinets, the depth of the inner space, i.e. the internal volume, can be changed by a user. Therefore, since the user can set acoustic signals generated from the speaker according to his/her taste, there is an advantage in that it is possible to increase the user's degree of satisfaction for the speaker.

Such an advantage can also be obtained by changing the length of the duct. That is, since the user can adjust the length of the duct provided within the cabinets, it is possible to use the speaker by differently setting the compass of acoustic signals according to his/her taste.

Next, in the present invention, the elastic member is used in supporting the rear end of the duct. Therefore, since it is not necessary to use an additional fastener, such as an adhesive or a screw, for supporting the rear end of the duct, an assembling process of the speaker is simplified. In addition, since vibrations are absorbed by the elastic member, the installation state of the duct can be securely maintained.

Finally, in the present invention, the structure in which the rear end of the duct is fixed by the elastic member can securely fix the duct to the interior of the cabinets without using an adhesive or a screw which cannot be applied to a cabinet made of a ceramic material.

1. A speaker, comprising:
a first cabinet with a predetermined inner space defined therein;
a second cabinet in which an inner space communicating with the inner space of the first cabinet is defined so that the inner space of the first cabinet is closed from the outside when the second cabinet is engaged with the first cabinet; and
a sound-generating unit provided in the inner spaces defined by the first and second cabinets to generate an acoustic signal,
wherein the first and second cabinets can move relatively with respect to each other, whereby an internal volume of the inner spaces is changed through adjustment of the length of the inner spaces between a front end of the first cabinet and a rear end of the second cabinet.

2. The speaker as claimed in claim 1, wherein the first and second cabinets are formed to take the shape of a cylinder, and an outer surface of one of the first and second cabinets and an inner surface of the other thereof are formed with thread portions corresponding to each other, respectively.

3. The speaker as claimed in claim 1, wherein a lower portion of an outer one of the first and second cabinets is provided with a base for supporting them on a floor.

4. The speaker as claimed in claim 1, wherein the exterior of an outer one of the first and second cabinets is provided with an enclosure.

5. The speaker as claimed in claim 1, further comprising a duct for causing the inner spaces defined by the first and second cabinets to communicate with the outside, wherein the length of the duct can be adjusted.

6. The speaker as claimed in claim 5, wherein the duct comprises a plurality of connected pipes with gradually varying inner diameters, thereby adjusting the length of the duct.

7. The speaker as claimed in claim 1, further comprising a duct for causing the inner spaces defined by the first and second cabinets to communicate with the outside, wherein a rear end of the duct is supported at the second cabinet by an elastic member.

8. The speaker as claimed in claim 7, wherein the duct is provided with a rear end flare portion of which an inner diameter increases toward the rear end of the duct, and one end of the elastic member is seated in the rear end flare portion and the other end thereof is fixed to the second cabinet to support the duct.

9. The speaker as claimed in claim 8, further comprising gaskets between the rear end of the duct and the elastic member and between a front end of the duct and an inner connection portion of the first cabinet connected thereto, respectively, thereby absorbing vibrations.

10. The speaker as claimed in claim 7, wherein the first and second cabinets are made of a ceramic material.
